(19) United States
(12) Patent Application Publication
(10) Pub. No.: US 2011/0073750 A1
(43) Pub. Date: Mar. 31, 2011

(54) IMAGE PICKUP APPARATUS AND RADIATION IMAGE PICKUP SYSTEM

(75) Inventors: Kazumi Nagano, Fujisawa-shi (JP); Satoshi Okada, Tokyo (JP); Masato Inoue, Kumagaya-shi (JP); Shinichi Takeda, Honjo-shi (JP); Keiichi Nomura, Honjo-shi (JP); Satoru Sawada, Kodama-gun (JP); Yohei Ishida, Honjo-shi (JP); Akiya Nakayama, Kawasaki-shi (JP)

(73) Assignee: CANON KABUSHIKI KAISHA, Tokyo (JP)

(21) Appl. No.: 12/884,053

(22) Filed: Sep. 16, 2010

(30) Foreign Application Priority Data
Sep. 28, 2009 (JP) 2009-222511

(51) Int. Cl. H01L 27/00

(52) U.S. Cl. 250/208.1

(57) ABSTRACT

An image pickup apparatus includes an insulating substrate, and a plurality of pixels each including a conversion element configured to convert incident light or radiation into a charge and also including a switch element configured to transfer an electric signal corresponding to the charge generated by the conversion element. Gate wiring is configured to drive the switch element to transfer the electric signal through signal wiring. The plurality of pixels, the signal wiring, and the gate wiring are disposed on one surface of the insulating substrate. The insulating substrate has vias that provide electrical connections between the one surface and an opposite surface of the insulating substrate.

### BACKGROUND OF THE INVENTION

1. Field of the Invention

The present invention relates to an image pickup apparatus suitable for use in radiation image pickup and a system therefor.

2. Description of the Related Art

An image pickup apparatus suitable for radiation image pickup is known. Such an image pickup apparatus typically has a radiation detection substrate that includes a plurality of pixels each including a thin film transistor (TFT) and a photoelectric conversion element disposed on a glass substrate. External circuits such as a driving circuit and a signal processing circuit are disposed in close vicinity of the glass substrate such that signals are transmitted between the external circuits and the radiation detection substrate.

For connection with the external circuits disposed in close vicinity of the glass substrate, connection terminals are formed only on certain regions of the glass substrate. Regions other than the certain regions of the glass substrate contain no connection terminals. Thus, edges of an effective imaging area are allowed to be positioned close to outer edges of the glass substrate. An example of the above-described structure is disclosed in Japanese Patent Application Laid-Open No. 2002-314056.

In an image pickup apparatus, an image sensor has an effective sensing area and a non-sensing area (frame area) surrounding the effective sensing area. The non-sensing area or frame area is used for disposing the above-described connection terminals. However, in the image pickup apparatus having such a configuration, the width of the frame area on the sides of the glass substrate where connection terminals are disposed reduces the effective sensing area of the image sensor. Therefore, there is a need for minimizing the non-sensing area or frame area and increasing the effective sensing area of this type of image sensors.

### SUMMARY OF THE INVENTION

In view of the above, the present invention provides a small-size image pickup apparatus and radiation image pickup apparatus with a sufficiently large imaging area and a radiation image pickup system using such a radiation image pickup apparatus.

In accordance with at least one embodiment of the present invention, an image pickup apparatus comprises an insulating substrate, a plurality of pixels each including a conversion element configured to convert incident light or radiation into a charge and also including a switch element configured to transfer an electric signal corresponding to the charge generated by the conversion element, a signal wiring configured to transfer the electric signal, and a gate wiring configured to drive the switch element, wherein the plurality of pixels, the signal wiring, and the gate wiring are disposed on one surface of the insulating substrate, and wherein the insulating substrate includes one or more vias that provide electrical connections between the one surface and an opposite surface of the insulating substrate.

The configuration described above makes it possible to minimize the frame area, which allows an increase in the imaging area and thus it becomes possible to achieve a small-size image pickup apparatus with a large imaging area.

Further features of the present invention will become apparent to persons having ordinary skill in the art from the following description of exemplary embodiments with reference to the attached drawings.

### BRIEF DESCRIPTION OF THE DRAWINGS

FIG. 1 is a diagram illustrating a configuration of an image pickup apparatus according to an embodiment of the present invention.

FIG. 2 is a plan view illustrating a configuration of a pixel of the image pickup apparatus shown in FIG. 1.

FIG. 3 is a cross-sectional view of the image pickup apparatus shown in FIG. 2 taken along a line III-III of FIG. 2.

FIG. 4 is a cross-sectional view of the image pickup apparatus shown in FIG. 2 taken along a line IV-IV of FIG. 2.

FIG. 5 is a plan view schematically illustrating an image pickup apparatus shown from a front side according to an embodiment of the present invention.

FIG. 6 is a plan view schematically illustrating the back side of the image pickup apparatus shown in FIG. 5.

FIG. 7 is a plan view of an image pickup apparatus shown from a front side according to another embodiment of the present invention.

FIG. 8 is a plan view schematically illustrating the back side of the image pickup apparatus shown in FIG. 7.

FIG. 9 is a cross-sectional view illustrating an image pickup apparatus contained in a housing according to a further embodiment of the present invention.

FIG. 10 is a diagram illustrating an example of a radiation image pickup system using an image pickup apparatus according to an embodiment of the present invention.

### DESCRIPTION OF THE EMBODIMENTS

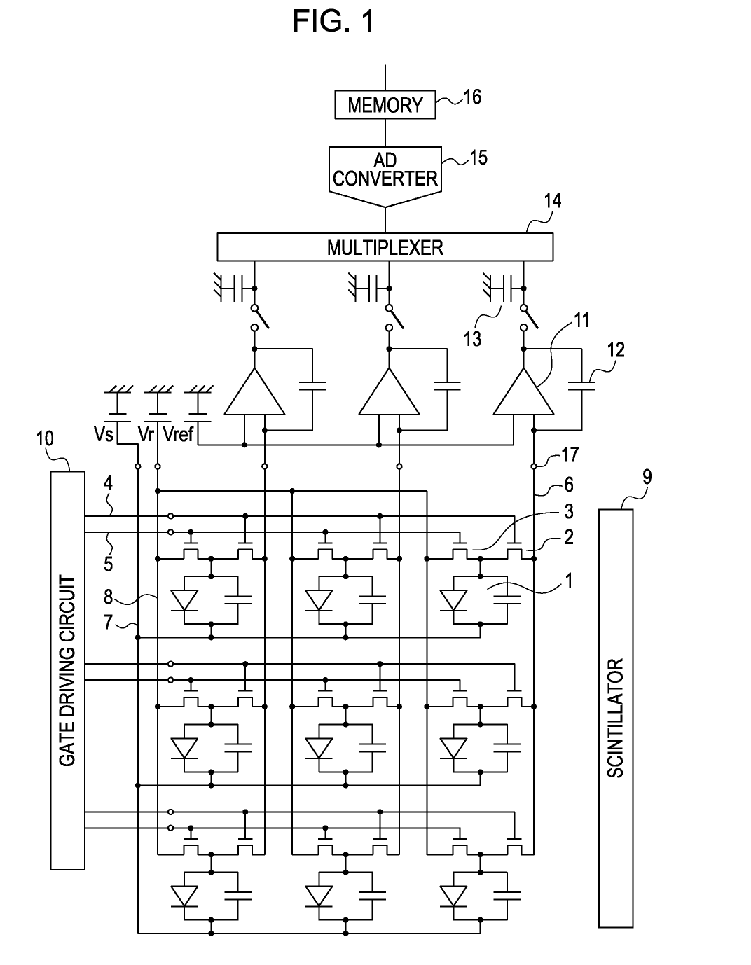

Embodiments of the present invention are described below with reference to FIGS. 1 to 10. In the drawings, like reference numbers indicate substantially identical or functionally similar elements.

### First Embodiment

FIG. 1 is a diagram schematically illustrating an image pickup apparatus according to a first embodiment of the present invention.

In FIG. 1, reference numeral 1 denotes a photoelectric conversion element, reference numerals 2 and 3 denote switch elements, reference numerals 4 and 5 denote gate wirings through which on/off-signals are transmitted to TFTs, and reference numeral 6 denotes a signal wiring. In the example shown in FIG. 1, a photodiode is used as the photoelectric conversion element 1, and a negative bias voltage is applied to the photodiode. That is, a cathode electrode of the photodiode is supplied with a positive bias voltage. A bias wiring 7 is used in common for a plurality of photodiodes and is connected to a power supply circuit Vs. A reset wiring 8 is used in common for the plurality of photodiodes and is connected to a power supply circuit Vr. As for the photoelectric conversion element 1, for example, a MIS-type or PIN-type thin-film photoelectric conversion element using a hydrogenated amorphous silicon film, a PN photodiode using single crystal silicon, or the like may be used. In the case where the photoelectric conversion element is used, a scintillator 9 is used to convert incident radiation such as an X-ray into visible light. Alternatively, a direct-conversion element may be used to directly convert an X-ray into an electric signal. As for the direct-conversion element, amorphous selenium, gallium arsenide, mercury iodide, lead iodide, cadmium telluride, or the like may be used. In the case where the direct-conversion element is used, the scintillator 9 is not necessary. Note that in a case where the image pickup apparatus is not for detection of radiation such as an X-ray but for detection of visible light or infrared light, no scintillator is used. As for the switch elements 2 and 3, a thin-film transistor (TFT) using amorphous silicon, polysilicon, or single crystal silicon, or a MOS transistor based on known technology may be used. The switch element 2 is used as a transfer switch element (hereinafter, referred to as a “transfer TFT”) configured to transfer (output) an electric signal corresponding to a charge generated by the photoelectric conversion element. The switch element 3 is used as a reset switching element (hereinafter, referred to as a “reset TFT”) configured to reset the photoelectric conversion element. Having defined the switch element 2 as the transfer TFT and the switch element 3 as the reset TFT, the remainder of the specification may interchangeably refer to switch elements 2 and 3 as the transfer TFT 2 and the reset TFT 3. The transfer TFT and the reset TFT are formed on an insulating substrate (not illustrated in FIG. 1). The insulating substrate has vias 17 for electrical connections between wirings disposed on one surface of the insulating substrate and wirings disposed on the opposite surface of the insulating substrate.

Reference numeral 10 denotes a gate driving circuit that controls the switch elements 2 and 3 by supplying driving signals thereto through gate wirings 4 and 5. Reference numeral 11 denotes a first-stage integrating amplifier that reads a charge generated in the photoelectric conversion element 1. Reference numeral 12 denotes integrating capacitance of the first-stage integrating amplifier. Vref denotes a power supply circuit for the first-stage integrating amplifier. Reference numeral 13 denotes a sample-and-hold circuit that samples and holds the signal. Reference numeral 14 denotes a multiplexer that outputs signals while sequentially switching the sampled-and-held signals. Reference numeral 15 denotes an analog-to-digital (AD) converter that converts the signal output from the multiplexer 14 into a digital signal. Reference numeral 16 denotes a frame memory.

Next, a method of driving the image pickup apparatus shown in FIG. 1 is described below. First, when an X-ray is incident on the image pickup apparatus, the incident X-ray is subjected to a wavelength conversion. More specifically, the incident X-ray is converted by the scintillator 9 into visible light. The resultant visible light is incident on the photoelectric conversion element 1 and converted into a charge. The generated charge is accumulated in the photoelectric conversion element 1. If the gate driving circuit 10 turns on the transfer TFT 2 through the gate wiring 4, an electric signal based on the charge accumulated in the photoelectric conversion element 1 is transferred to the integrating capacitance 12 of the first-stage integrating amplifier 11, and converted to a voltage signal. The voltage signal is then sampled and held by the sample-and-hold circuit 13. An analog signal based on the sampled and held voltage signal is sequentially read by the multiplexer 14 and converted into a digital signal by the analog-to-digital converter 15. The resultant digital signal is stored in the frame memory 16. By performing the reading operation described above repeatedly for the respective gate wirings 4, a two-dimensional image including 3×3 pixels is obtained. Before the reading operation to obtain a next frame of image is started, the photoelectric conversion element 1 is reset by reset TFT 3. More specifically, the reset TFT 3 turns on in response to a signal supplied through the gate wiring 5 from the gate driving circuit 10, and thus the photoelectric conversion element 1 is reset by a voltage supplied from the power supply Vr. Note that in the example described above, for the purpose of simplicity, it is assumed that only 3×3 pixels are arranged in the form of a matrix, although the actual image sensor may be configured in the form of a large area sensor including 1000×1000 or more pixels.

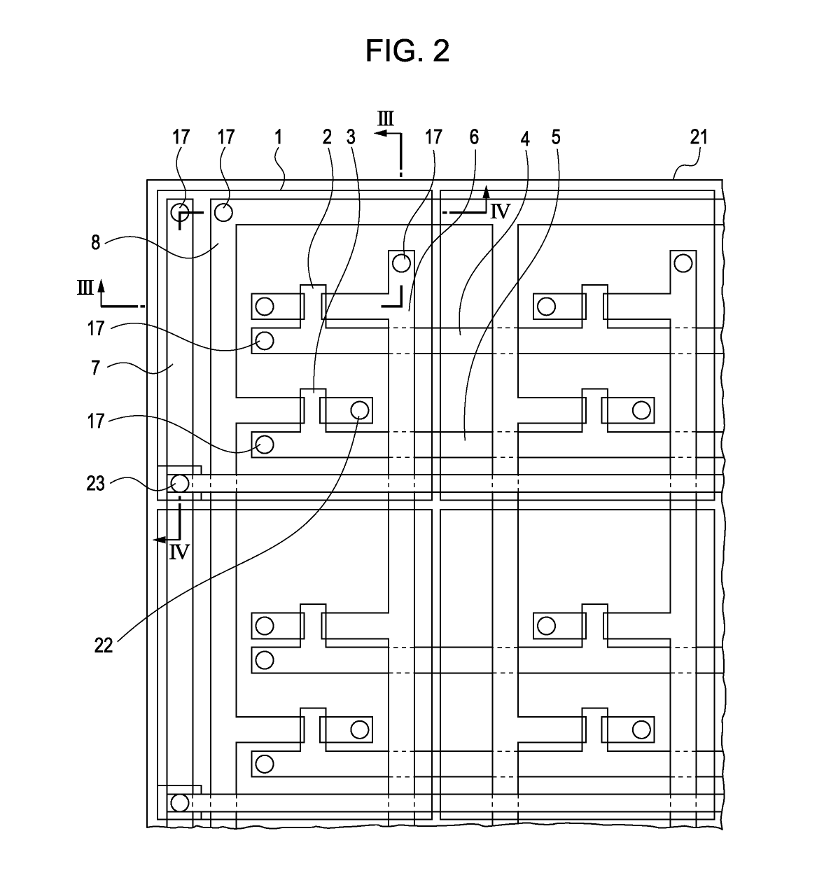

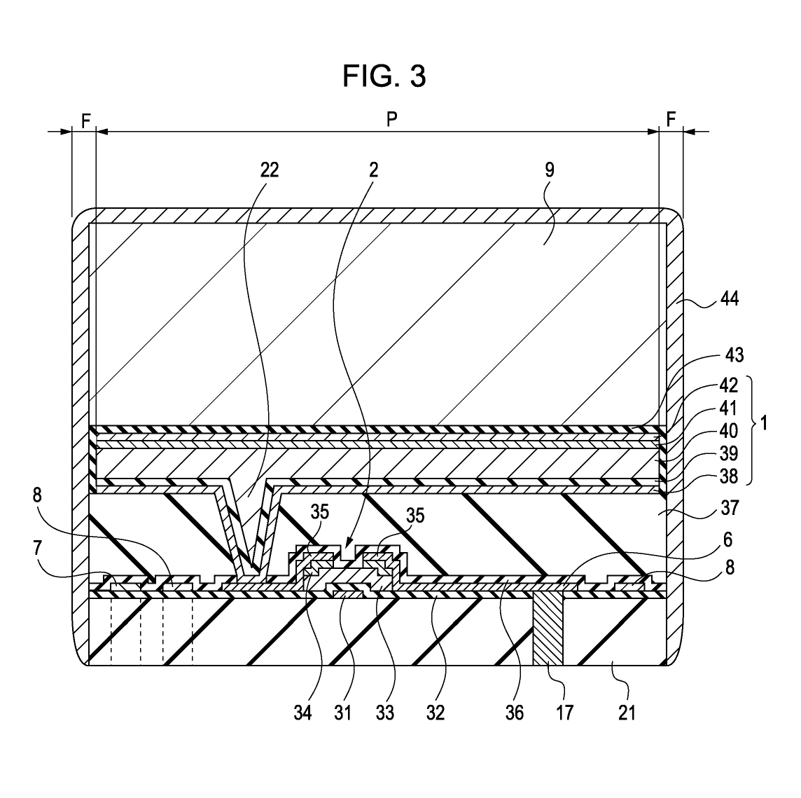

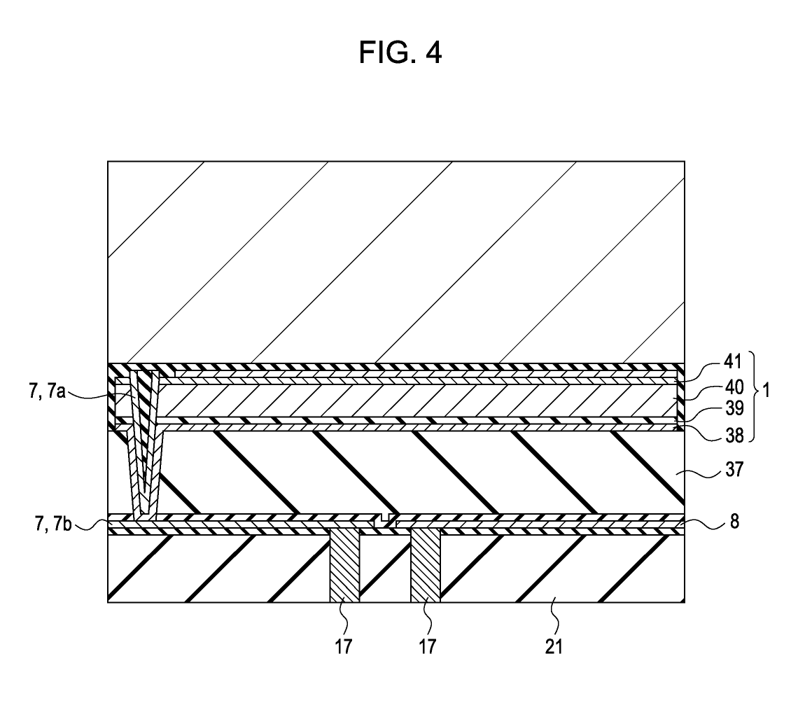

Next, the details of the pixels of the image pickup apparatus are described below. FIG. 2 is a plan view illustrating 2×2 pixels disposed on an insulating substrate 21. FIG. 3 is a diagram illustrating a structure of one pixel in a cross section taken along a line III-III of FIG. 2. FIG. 4 is a diagram illustrating a structure of one pixel in a cross section taken along a line IV-IV of FIG. 2.

As shown in FIG. 2, each pixel includes a photoelectric conversion element 1, a transfer TFT 2 that transfers a charge generated by the photoelectric conversion element 1 as a result of the photoelectric conversion, and a reset TFT 3 that resets the photoelectric conversion element 1. One of the source/drain electrodes of the transfer TFT 2 is connected to a signal wiring 6, and one of the source/drain electrodes of the reset TFT 3 is connected to a reset wiring 8. A bias wiring 7 is connected to the photoelectric conversion element 1. A gate wiring 4 for the transfer TFT, a gate wiring 5 for the reset TFT, the signal wiring 6, the bias wiring 7, and the reset wiring 8 are connected to corresponding vias 17. The vias 17 are disposed inside an area of insulating substrate 21 in which the plurality of pixels are arranged. More specifically, the vias 17 are disposed on the periphery of the area in which photoelectric conversion elements 1 are arranged. Reference numeral 22 and 23 indicates through-hole portion.

As shown in FIG. 3, each pixel has a multilayer structure in which the photoelectric conversion element 1 is disposed on the transfer TFT 2. The transfer TFT 2 is disposed on one surface of the insulating substrate and includes a gate electrode 31, a gate insulating layer 32, a semiconductor layer 33 serving as a channel layer, an n-type conductive semiconductor layer 34, and source/drain electrodes 35. The transfer TFT 2 and the wirings 6 to 8 are covered with an insulating layer 36. The photoelectric conversion element 1 is disposed above the transfer TFT 2, and an insulating layer 37 is disposed between the transfer TFT 2 and the photoelectric conversion element 1. The photoelectric conversion element 1 is formed in a MIS (metal-insulator-semiconductor) type using amorphous silicon with a structure including a lower electrode 38 made of ITO (indium tin oxide), an insulating layer 39, an i-type (intrinsic) semiconductor layer 40, an n-type conductive semiconductor layer 41, and an upper electrode 42 made of ITO. Reference numeral 22 indicate through-hole portion. The photoelectric conversion element 1 is covered with an insulating layer 43. A scintillator 9 is disposed on the insulating layer 43. A protective layer 44 is disposed such that side faces of the insulating substrate 21 and the surface of the scintillator 9 are covered with the protective layer 44. The pixel including the photoelectric conversion element 1 is disposed in an imaging area P surrounded by a frame area (F). The insulating substrate 21 has a conductive via 17 through which a signal based on the charge generated by the photoelectric conversion element 1 is transferred to the opposite surface of the insulating substrate 21. The via 17 is formed as follows. First, a through-hole is formed in the insulating substrate 21 by a known micro-machining method, such as laser ablation or a micro blasting process. Subsequently, an inner wall of the through-hole is covered with a conductive material by plating or filling a conductive paste. Although in the example shown in FIG. 3, the via 17 has a shape in which the through-hole is filled with a conductive material, only the inner surface of the through-hole may be covered with the conductive material and the through-hole may have a non-filled space. The insulating substrate may be formed of transparent low-alkaline glass, a resin, or other similar materials.

As shown in FIG. 4, to supply a bias voltage to the photoelectric conversion element 1, an upper bias wiring 7a disposed on the photoelectric conversion element 1 is connected to a lower bias wiring 7b disposed on the insulating substrate 21 through the lower electrode 38. To realize the connection, a through-hole is formed in the insulating layer 37, the insulating layer 39, the intrinsic semiconductor layer 40, and the conductive semiconductor layer 41. When the upper bias wiring 7a and lower bias wiring 7b are directly connected, the lower electrode 38 is not necessary. As in FIG. 3, the bias wiring 7 and the reset wiring 8 are connected to vias 17 to make it possible the transfer of signals from one surface to the other surface of the insulating substrate 21.

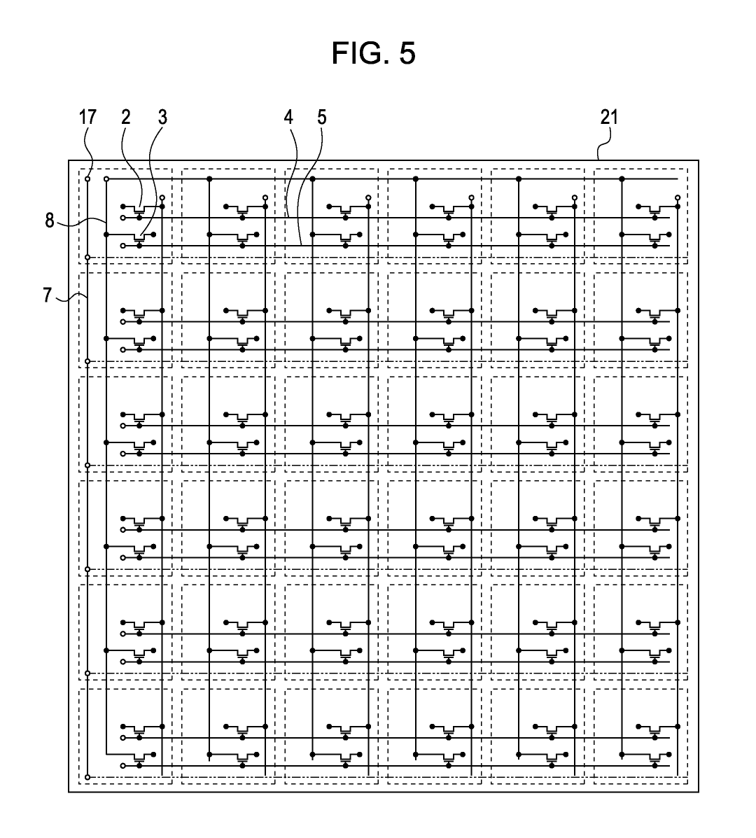

FIG. 5 is a plan view of 6×6 pixels of the image pickup apparatus as seen from one side of the insulating substrate 21. Vias 17 are formed in a peripheral area of the insulating substrate 21 to provide electrical connections between upper and lower surfaces (first and second surfaces) of the insulating substrate 21 for wirings such as the gate wiring 4, the gate wiring 5, the signal wiring 6, the bias wiring 7, and the reset wiring 8.

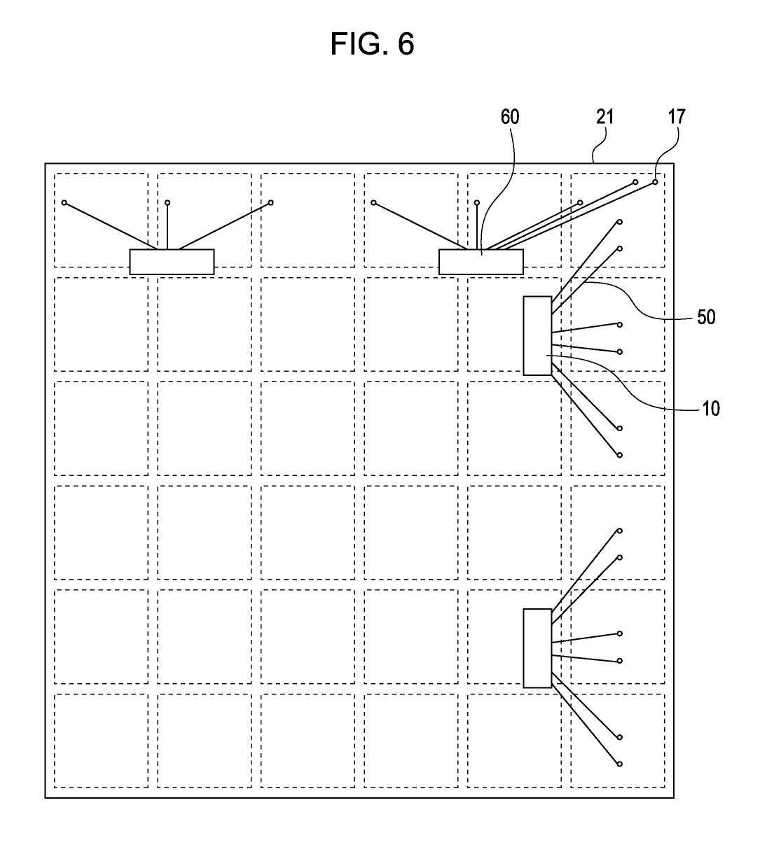

FIG. 6 illustrate a plan view of 6×6 pixels of the image pickup apparatus as seen from the other side of the insulating substrate 21. As shown in FIG. 6, vias 17 are connected to the gate driving circuit 10 or the signal processing circuit 60 through connection wirings 50. The gate driving circuit 10 is configured to supply a TFT driving signal to the transfer TFT 2 or the reset TFT 3 through vias 17. A signal transferred by the transfer TFT 2 is detected by the signal processing circuit 60. The signal processing circuit 60 includes at least a first-stage integrating amplifier 11 and integrating capacitance 12, and may further include a sample-and-hold circuit 13 and an analog-to-digital converter 15.

In the present embodiment, as described above, the vias 17 are disposed inside the area of the insulating substrate 21 in which the plurality of pixels are arranged, and more specifically, the vias 17 are disposed on the periphery of the area of the insulating substrate 21 in which photoelectric conversion elements 1 are arranged. This configuration allows a reduction in the frame area and thus it is possible to realize a small-size image pickup apparatus having a sufficiently large imaging area.

### Second Embodiment

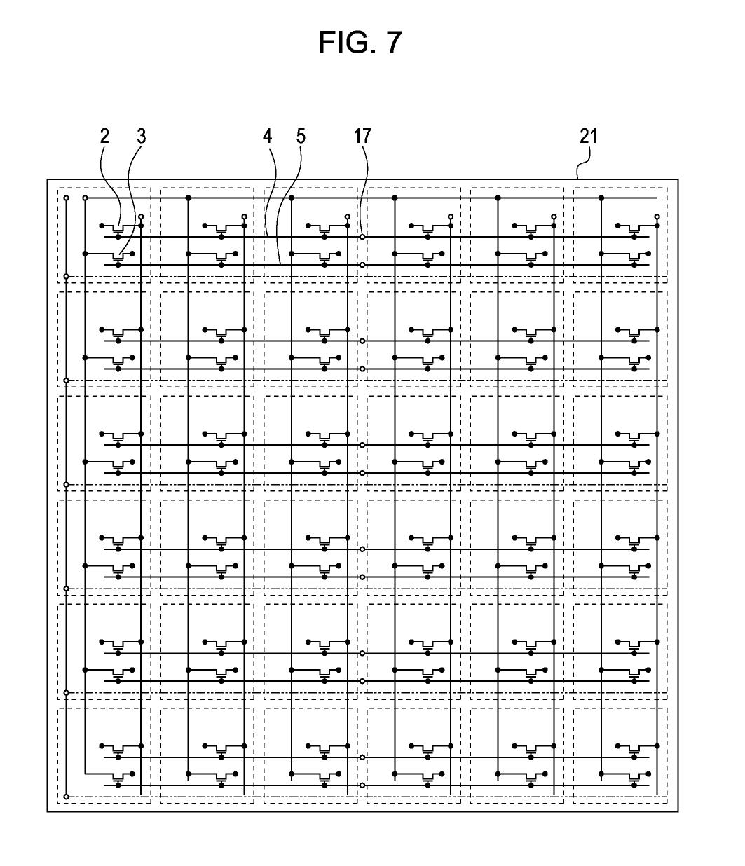

FIG. 7 is a plan view illustrating 6×6 pixels of an image pickup apparatus according to a second embodiment, as seen from one side of an insulating substrate 21. The image pickup apparatus according to this embodiment is different from that according to the first embodiment in that vias 17 connected to gate wirings 4 and 5 are formed at different locations in the insulating substrate 21.

As shown in FIG. 7, one of the vias 17 is connected to a gate wiring 4 for transfer TFTs 2 and another one of the vias 17 is connected to a gate wiring 5 for reset TFTs 3. Each via 17 is disposed at the middle, as seen in the direction in which the gate wirings extend, of the corresponding gate wiring connected to a row of pixels (6 pixels in this embodiment). More specifically, in FIG. 7, vias 17 connected to gate wirings 4 and 5 are disposed at the middle of the area of the insulating substrate 21 occupied by each row of pixels.

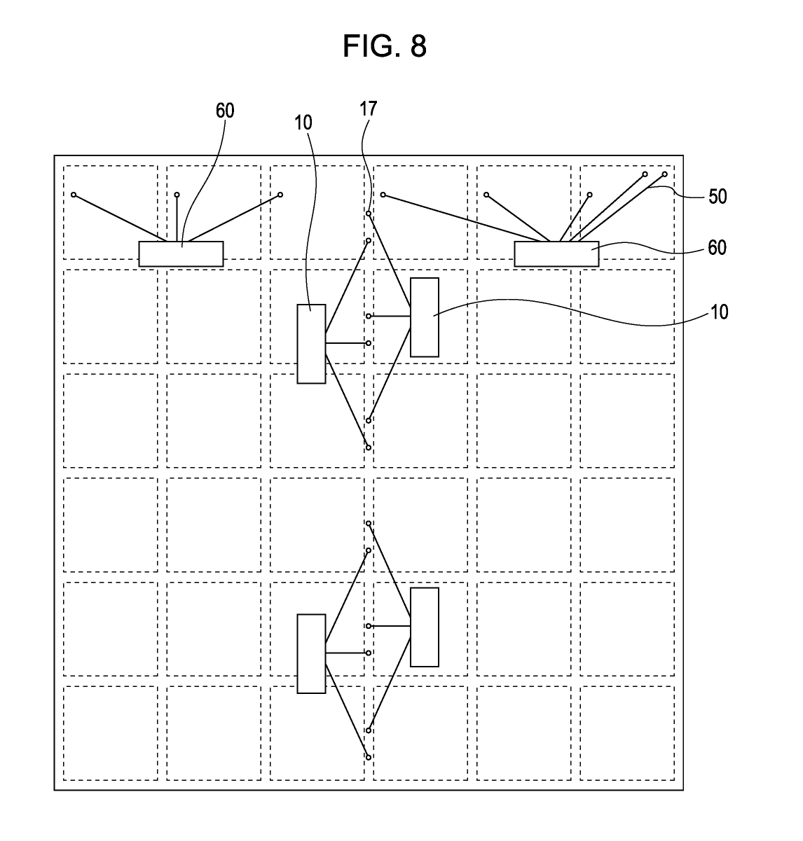

FIG. 8 is a plan view of 6×6 pixels of the image pickup apparatus as seen from the other surface opposite to the one surface of the insulating substrate. One gate driving circuit 10 is used to drive the transfer TFTs 2, and one gate driving circuit 10 is used to drive the reset TFTs 3. This configuration allows each gate driving circuit to have a large wire-to-wire pitch, which allows simplification of production process.

Disposing the vias 17 at the middle of each row of pixels in the insulating substrate 21 leads to a reduction in the distance from the gate driving circuit 10 to a farthest point of the gate wiring. This results in a reduction in signal propagation delay due to resistance of the gate wiring, which makes it possible to efficiently transmit signals. Thus, it becomes possible to obtain a high-quality image. In the present embodiment, there are the same number of pixels in both ranges from the point at which the gate wiring is connected to the via 17 to either end of the gate wiring. However, the number of pixels or the distance may be different between the two ranges as long as the difference does not cause a significant difference in signal propagation delay. Practically, a difference of 10% in the number of pixels or distance is allowable. Therefore, the middle of each row of pixels as seen in the direction in which the gate wiring extends may be determined within a tolerance of 10% of the distance or the number of pixels.

Each of gate wirings 4 and 5 does not necessarily need to be connected to only one via 17. Any gate wiring may be connected to two or more vias 17 disposed at different locations. Connecting the gate wiring to two or more vias 17 provides an advantage that even if a disconnection occurs in the gate wiring, the disconnection exerts an influence on a smaller number of pixels than in the case in which the gate wiring is connected to only one via. In the case where a gate wiring is connected to two or more vias 17, the pixels connected to the gate wiring may be divided into a plurality of groups and each group may have one via 17 disposed at the middle of the group.

### Third Embodiment

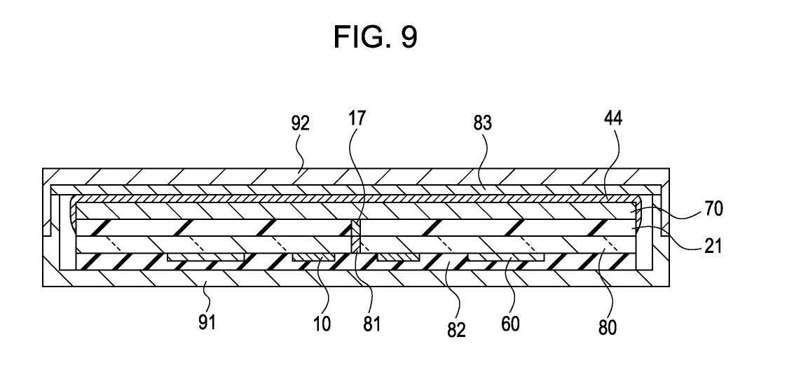

FIG. 9 is a cross-sectional view of an image pickup apparatus having a two-part housing according to a third embodiment of the invention.

In FIG. 9, reference numeral 70 denotes a conversion unit including transfer and reset TFTs, photoelectric conversion elements, and scintillators (not shown) arranged on an insulating substrate 21. Reference numeral 80 denotes a circuit board on which a gate driving circuit 10, a signal processing circuit 60, etc. are disposed. Reference numeral 81 denotes a via formed in the circuit board 80. Reference numeral 82 denotes an insulating layer having thermal conductivity covering the circuit board 80. Reference numeral 83 denotes a protective layer. Reference numerals 91 and 92 denote two parts of the housing.

The via 81 of the circuit board 80 is connected to a via 17 formed in the insulating substrate 21. In the example shown in FIG. 9, the via 81 of the circuit board 80 is formed in the shape of a through-hole. In a case where an internal wiring is disposed in the circuit board 80, the via 81 does not necessarily need to be in the shape of a through-hole. The circuit board 80 may be formed using glass epoxy as a material. The circuit board 80 also serves to support the insulating substrate 21. In a case where the insulating substrate 21 is made of glass or the like, the circuit board 80 protects the insulating substrate 21 from vibrations or other impacts. The gate driving circuit 10 and the signal processing circuit 60 are disposed on a surface of the circuit board 80 opposite to a surface thereof that is in contact with the insulating substrate 21.

A thermally conductive insulating layer 82 is a thermally conductive resin film made of a resin containing a thermal conductive filler such as a ceramic filler, a graphite filler, or the like. The thermally conductive insulating layer 82 serves to transfer heat generated in the signal processing circuit 60 or the like to the housing such that the heat is radiated to the outside. Although resins usually have a thermal conductivity in a range from 0.1 to 0.6 W/m·K (Watts per Kevin per meter), the thermal conductivity of the thermally conductive resin film 82 is preferably in a range greater than 5 W/m·K and more preferably in a range greater than 10 W/m·K. The thermally conductive resin film has a base of silicone or the like. The thermally conductive resin film has flexibility, which allows it to protect the gate driving circuit 10, the signal processing circuit 60, and other parts from vibrations and other impacts.

### Fourth Embodiment

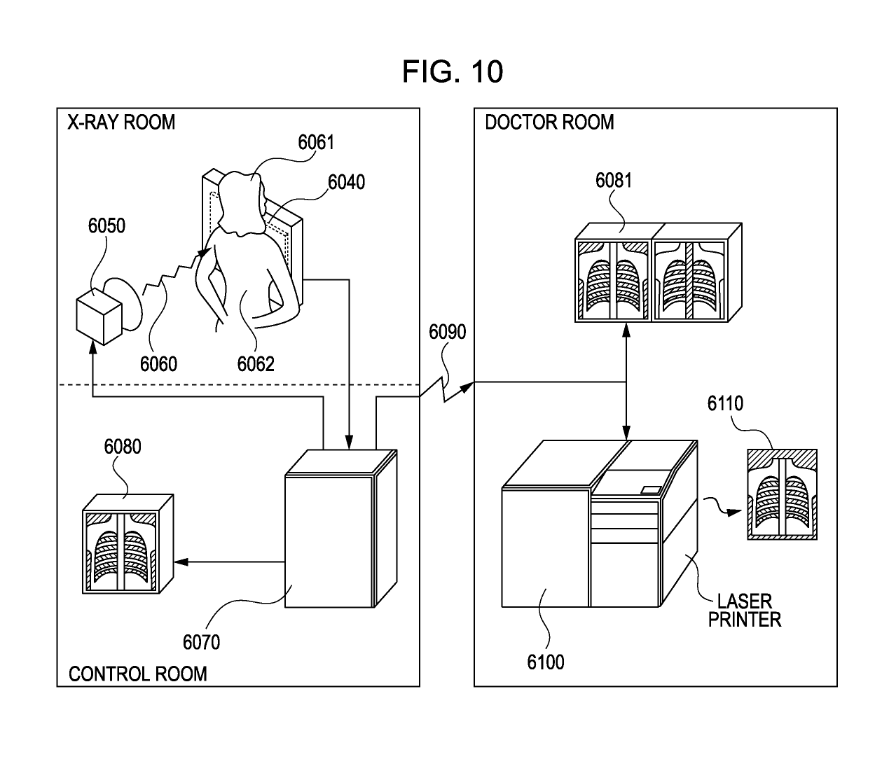

FIG. 10 is a diagram illustrating an X-ray diagnosis system (radiation image pickup system) using an X-ray image pickup apparatus according to a fourth embodiment of the invention. X-ray radiation 6060 generated by an X-ray tube 6050 (radiation source) passes through a body part (e.g., chest) 6062 of a patient or subject 6061 under examination. The X-ray radiation after passing through the body part 6062 reaches a photoelectric conversion apparatus 6040 having a scintillator disposed on a top surface thereof. In this case, the photoelectric conversion apparatus 6040 serves as the radiation image pickup apparatus. The X-ray radiation incident on the photoelectric conversion apparatus 6040 includes information concerning the inside of the body of the patient 6061. In response to the incident X-ray radiation, the scintillator emits light. The emitted light is converted into electric information (as described above in reference to FIG. 1). The electric information is converted into a digital signal and is subjected to image processing by an image processor 6070 serving as a signal processing unit. A resultant image is displayed on a display 6080 serving as a display unit installed in a control room. Note that the radiation image pickup system includes at least an image pickup apparatus and a signal processing unit configured to process a signal received from the image pickup apparatus.

The obtained information may be transferred to a remote location by a transmission system such as a wired or wireless network system 6090 so that the information may be displayed on a display 6081 serving as a display unit installed in a doctor room at the remote location. Alternatively, the obtained information may be stored locally or remotely in a storage medium such as an optical disk (not shown). The transferred or stored information allows a doctor to make a diagnosis. The information may also be recorded on a film 6110 serving as a recording medium by a film processor 6100 serving as a recording unit, or may be printed by, e.g., a Laser Printer.

While the present invention has been described with reference to exemplary embodiments, it is to be understood that the invention is not limited to the disclosed exemplary embodiments. The scope of the following claims is to be accorded the broadest interpretation so as to encompass all modifications and equivalent structures and functions.

This application claims the benefit of Japanese Patent Application No. 2009-222511 filed Sep. 28, 2009, which is hereby incorporated by reference herein in its entirety.

What is claimed is:

1. An image pickup apparatus comprising:
an insulating substrate;
a plurality of pixels each including a conversion element configured to convert incident light or radiation into a charge and also including a switch element configured to transfer an electric signal corresponding to the charge generated by the conversion element;
a signal wiring configured to transfer the electric signal; and
a gate wiring configured to drive the switch element;
wherein the plurality of pixels, the signal wiring, and the gate wiring are disposed on one surface of the insulating substrate,
and wherein the insulating substrate includes one or more vias that provide electrical connections between the one surface and an opposite surface of the insulating substrate.

2. The image pickup apparatus according to claim 1, wherein the one or more vias are disposed inside an area in which the plurality of pixels are disposed.

3. The image pickup apparatus according to claim 1, wherein a via is connected to the gate wiring and is disposed in the middle, as seen in a direction in which the gate wiring extends, of a set of pixels connected to the gate wiring.

4. The image pickup apparatus according to claim 1 further comprising:
a driving circuit configured to output a driving signal applied to the switch element, the driving circuit being disposed on the opposite surface of the insulating substrate, and
a signal processing circuit configured to process the electric signal.

5. The image pickup apparatus according to claim 4 further comprising a circuit board disposed on the opposite surface of the insulating substrate and connected to the one or more vias of the insulating substrate,
wherein the driving circuit and the signal processing circuit are disposed on a surface of the circuit board opposite to the insulating substrate.

6. The image pickup apparatus according to claim 5 further comprising:
a housing,
a thermally conductive insulating layer made of a resin containing a thermally conductive filler, the thermally conductive insulating layer being disposed between the housing and both the driving circuit and the signal processing circuit.

7. A radiation image pickup system comprising:
a radiation image pickup apparatus according to claim 1; and
a signal processing unit configured to process a signal output from the radiation image pickup apparatus.

8. An image pickup apparatus comprising:
an insulating substrate having a first surface opposite to a second surface and including one or more vias that provide electrical connections between the first surface and second surface;
a plurality of pixels each including a conversion element configured to convert incident light or radiation into an electric signal and also including a switching element configured to output the electric signal from the conversion element to a processing circuit;
gate wiring and signal wiring configured to connect the conversion element and the switching element to the one or more vias;
a gate driving circuit configured to drive the switching element to transfer the electric signal from the conversion element to the processing circuit;
wherein the plurality of pixels, the gate wiring and the signal wiring are disposed on the first surface of the insulating substrate,
wherein at least one the gate driving circuit and the processing circuit is disposed on the second surface of the insulating substrate; and
wherein the electric signal is transferred from the conversion element to the processing circuit through the one or more vias of the insulating substrate.
